(19) United States
(12) Patent Application Publication
(10) Pub. No.: US 2007/0267121 A1
(43) Pub. Date: Nov. 22, 2007

(54) Method for Digitally Creating Lithephane-Type Images

(76) Inventors: Peter Kelly, Mount Kisco, NY (US); Joseph Mendillo, Poughkeepsie, NY (US); Patrick Pigott, Garrison, NY (US)

Correspondence Address: THE FARRELL LAW FIRM, P.C., 333 EARLE OVINGTON BOULEVARD, SUITE 701, UNIONDALE, NY, 11553, US

(21) Appl. No.: 10/584,678

(22) PCT Filed: Nov. 26, 2003
(86) PCT No.: PCT/US03/37994

§ 371 Date: Mar. 5, 2007

(30) Foreign Application Priority Data
Feb. 27, 2003 (US) 10/375233

(51) Int. Cl. G03F 7/00

(52) U.S. Cl. 156/58; 428/156

(57) ABSTRACT

A method and system for creating a lithophane-type image includes adjusting a 3-D representation of an electronically processed 2-D image based on light-transmission characteristics of a final material into which the lithophane-type image to be produced.

### BACKGROUND OF THE INVENTION

1. Field of the Invention

The invention relates generally to electronically controlled methods of relief sculptures. In particular, the invention relates to a method of creating a lithophane-type work.

2. Description of the Prior Art

Perhaps one of the most unusual and interesting art forms to emerge from the early 19th century is the lithophane. Generally credited as being invented in France in 1827, the earliest forms of lithophanes were actually produced in China many years before.

The concept of original lithophanes is simply this: a sheet of porcelain carved in varying degrees of thickness, when held to a light, would result in a highly detailed picture with the soft image quality of a mezzotint. This simple concept, however, was not easy to execute. Sheer artistry of high order was required to make a master carving from which the lithophanes could be molded.

The first lithophanes were individually carved entirely by hand. But shortly after their introduction, the artists reasoned that molds could be made, from which numerous pieces could be cast. To produce these molds, a sheet of wax was placed on a piece of plate glass. This provided sufficient transparency for the artist's guidance. The full thickness of the wax on the glass stopped all light, and any scratch or gouge produced varying degrees of gray. Therefore, an entire range of shading from dark to bright was available for a skilled artisan to bring to life.

The artist first drew his general design on the surface of the white wax. Then, with modeling knives, burnishers, and other tools, he sculpted the minute details of the subject chosen for reproduction. From the wax carving, when the master model maker finally approved it, a plaster cast was made. This was the original die, which was used in molding the porcelain bisque. A moist porcelain paste was then skillfully pressed into this cast, picking up all the details in the carving. Close examination of this mold would reveal intricate surface detail.

During the porcelain casting process, the friction of the clay would swiftly wear these fine details out. Sometimes, as few as 20 castings would leave the image in the mold worn out. To address this problem, the artists developed master molds. Master molds were made out of a harder plaster than the production molds, and the image was reversed; like a negative. Production molds were then cast from the master mold, allowing many more lithophanes to be successfully cast. The seemingly simple process of removing the thin moist panels from the molds required the highest degree of skill to avoid damaging the intricate details in the image. Since the panels were very thin and delicate, and the kilns extremely hot, many fired pieces were warped, twisted and cracked. In addition, any slight impurity in the porcelain clay body showed up when the fired pieces were lit from behind. Therefore, the number of acceptable finished pieces to, come out of the kilns has always been far less than the number that went in. Sometimes, only about 40 percent of the panels survived this process.

U.S. Pat. Nos. 6,306,470 and 6,287,4924 disclose a method and apparatus for forming lithophane pictorial works by compressing pliant translucent material. Aimed primarily at those of low skill level, both references disclose a 3-D surface contoured to be the reversed image of the desired lithophane work, which is produced upon compressing pliant translucent material against the contoured surface.

In accordance with the inventive concept disclosed in these patents, a contoured surface is prefabricated, and serves as a master die. While being an entertaining toy, this method is no more than the replica of the traditional method and, thus, if considered as a whole including mold production, is a complex, scrupulous and highly technical process requiring high-skill professional manual levels.

With the advent of the computerized systems, a few attempts have been made to digitize emboss dies. U.S. Patent Application Publication No. 2002/0174929 discloses such traditional steps as initially creating a 3-D surface, forming the translucent impression of the copied 3-D, and then forming a 2-D file based on the captured 2-D image of the impression. Following the creation of the 2-D image, each of X and Y values of the 2-D image is grayscaled, and based on the scaled values, a Z height or thickness value is electronically determined. All of the scaled values are electronically inputted to a numerically controlled machine configured to produce the 3-D die.

In summary, the above-mentioned disclosure teaches creating an emboss die by a complicated process involving creating an initial 3-D sculpture or image, which, while indulging the creativity of the artist, critically slows and complicates the entire process. Accordingly, the process can be practiced by high-level professionals who are primarily interested in creating a master mold, not lithophane-type works.

It is therefore desirable to further develop a cost-efficient, mass-production process of forming 3-D images on translucent surfaces utilizing a lithophane technique.

### SUMMARY OF THE INVENTION

The inventive method greatly facilitates the traditional method by creating a lithophane-type image based on any 2-D image. In practice, the inventive method can start with any photographic or pictorial 2-D work inputted into a system for converting the 2-D image into a 3-D electronic file or a tooling model of the lithophane-type work.

In accordance with one aspect of the invention, a 2-D image may be digitized by a two-step process, in which the 2-D image is first scanned and then inputted into an inventive system providing the user with the 2-D image. Alternatively, a 2-D image, for example, a photograph made by a digital camera, can be directly inputted into the inventive system for further processing leading to the creation of the 3-D electronic file or actual model.

Based on the principle of the lithophane technique, the light transmission through the 3-D image is a function of the actual opacity of a given material and the thickness of 3-D tooling model made of such a material. In practical terms, the 3-D image formed on the tooling model can be lighter or darker depending on the thickness of the surface carrying the 3-D image. Hence, in accordance with another aspect of the invention, the inventive system allows for the optimization of the thickness of the model during the creation of the lithophane-type work.

The inventive method can be easily practiced in such vastly different industries including, for example, food and furniture manufacturing industries operating with a variety of materials. For instance, one aspect of the invention provides for an article, such as a cap for soda or wine bottles, having a generally cylindrical cross-section with one of the opposite ends open and the opposite end carrying a 3-D lithophane-type work. The single criterion applied to any given material to be ;used-in the inventive method is an appropriate transparency/thicmness ratio.

It is therefore an object of the invention to create a lithophane-type work in a simple, quick and cost-efficient manner.

Another object of the invention is to provide a computer-controlled method of creating a lithophane-type work.

Another object of the invention is to provide a computerized system for carrying out the inventive method.

Yet another object of the invention is to provide a variety of commercially available items and goods with lithophane-type 3-D images produced by the inventive method.

### BRIEF DESCRIPTION OF THE DRAWINGS

The above and other objects, features and advantages will become more readily apparent from the description of the preferred embodiment accompanied by the following drawings, in which:

FIG. 1 is a view of an inventive system;

FIG. 2 is a flowchart of the inventive method;

FIG. 3 is a flow chart of another embodiment of the inventive method;

FIG. 4 is perspective view of the lithophane work formed on a cap-like model;

FIG. 5 is a cross-sectional elevation view of another lithophane work;

FIG. 6 is a top view of the lithophane work shown in FIG. 5;

FIG. 7 is a top view of still another lithophane-type work made on a food item; and

FIG. 8 is a cross-sectional view of the item shown in FIG. 7.

### SPECIFIC DESCRIPTION

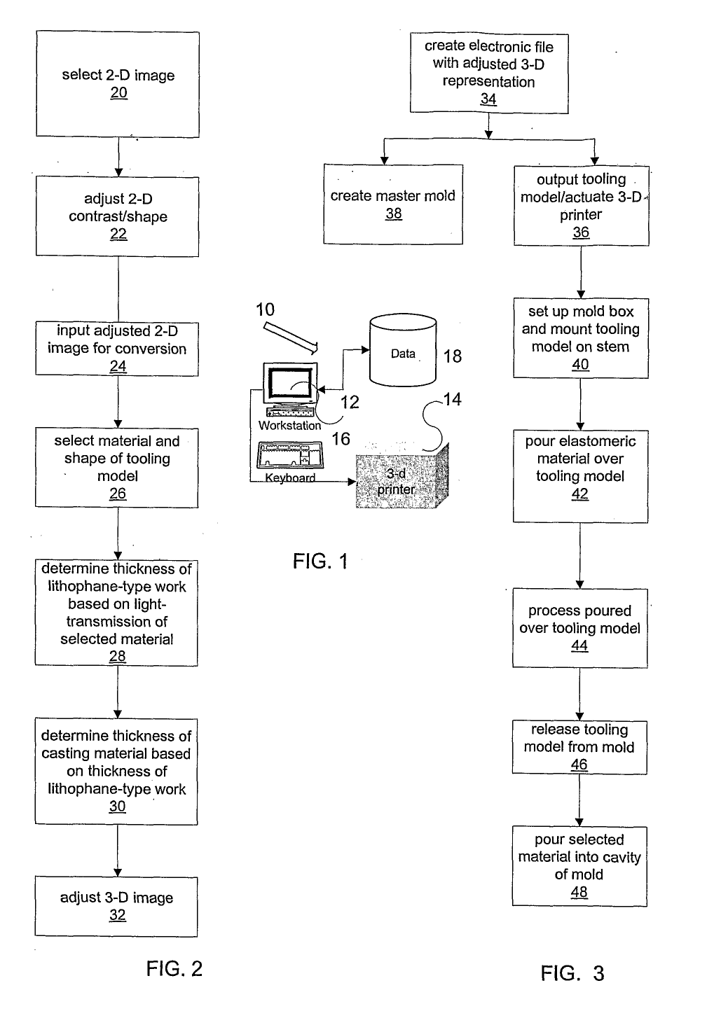

Referring to FIG. 1, a computerized system 100 for creating a lithophane type work allows for capturing a 2-D image by a CPU 12. The captured image can be manipulated by means of a keyboard 16 and, after necessary adjustment, software executing on the CPU 12 is adapted to convert the adjusted 2-D image into a 3-D representation thereof.

Thus, the inventive system 10 is compact and cost efficient. One of the unique components of the system 10 is a 3-D printer 14 (Thermojet) operated by software executing on the CPU 12. In principle, the 3-D printer 14 operates with a formable material, such as wax, and is configured to erect a 3-D tooling model mirroring the shape of the final product to be later molded based on the printed model.

Referring to FIGS. 2 and 3, the inventive process carried out by the system 10 starts with selection of a 2-D image at box 20. The advantage of the inventive method over the prior art known methods is it simplicity. In contrast to creating a 3-D impression on material and further capturing the latter as a 2-D image only to be reconverted into a digital 3-D image, the inventive method allows creating the 3-D representation based on the selected 2-D image. Thus, the inventive method is time-efficient since it does not require making a physical 3-D model. In fact, the goal of the inventive method is making such a 3-D model or creating an electronic file, as shown at boxes 34 and 36. In particular, the 2-D image is first adjusted at box 22 by enhancing the contrast of the image, and if the latter is captured in colors, by converting it into a black/white representation. Such an adjustment can be performed by programs including, but not limited to Adobe™ Photoshop™ allowing the white and black points to be adjusted to the satisfaction of the user.

Inputting the 2-D image into the 3-D conversion software, as indicated by box 24, can involve scanning and further actual loading of the scanned image into the conversion software. Alternatively, inputting of the selected 2-D image can be done directly without the necessity of scanning. For instance, an electronically stored or made photograph can be directly inputted into the conversion software of the CPU 12. Conversion includes transformation of a 2-D image (x, y) into a 3 dimensional (x, y, z) where the gray value of each pixel correlates to the height of the 3-D image at the x, y location. Among numerous 3-D conversion programs, Freeform has produced outstanding results.

The quality of the lithophane-type work, as indicated by box 26, is directly associated with the shape, material and color of the final product to be lithophaned, which can be chosen from, but not limited to bottle caps, key chains, souvenirs, eatable products, such as chocolate, caramel and others. The selection of the final product is largely determined by its light-transmission characteristics. The image of the final product is either created or retrieved from the system's database 18 (FIG. 1) by means of software executing on the CPU 12.

The principle of the lithophane-type techniques is based on the known law of optics postulating that the intensity of light passing through a homogeneous translucent material is inversely proportional to the thickness of the material. Accordingly, the dimensions of the lithophane-type work including its depth and thickness are critical to a high-quality lithophane-type work sculpted on the final product. To optimize the contrast of the lithophane work, the ratio between the thick and thin regions on the lithophaned surface of the final product, which corresponds to the dark and light spots on the grayscale, should be properly selected. In practical terms, the darker the spot, the thicker the region; conversely, the thinner the region, the lighter the spot. Excessive minimization of the difference between the thick and thin surface regions would lead to a poor contrast, whereas overly maximizing this difference would cause manufacturing problems and image distortion. In summary, to extrapolate input threshold levels of a grayscale image to produce a lithophane (3-D rendered image), software executing on the CPU 12 is adapted to calculate the thickness and depth of the lithophane as a function of the opacity of the final product's material. (FIG. 1, box 28) If the surface of the final product is not sufficiently dimensioned (thick) to allow the lithophane-type work to be produced in accordance with the determined threshold levels, this work may be formed not within the existing surface, but erected on the top of this surface. Alternatively, the surface of the final product maybe thickened to have the lithophhane-type work sculpted within it.

Turning momentarily to FIG. 3, if a model (prototype) of final product is manufactured by the printer 14, a tooling model made from casting material is outputted from the printer (box 36) and further mounted on a gated stem (box 40), and poured over by elastomeric material (box 42). As a result, a mold is formed which, after being processed under the desired pressure and at the desired temperature (box 44), has a mold cavity formed with the desired relief upon removal of the model from the cavity. See box 46. The cavity can be repeatedly filled with the material, from which the final product is made, as shown in box 48.

Returning to FIG. 2, since the desired depth of the final lithophane has been determined as a function of the opacity of the material o the final product, it is possible to determine the desired thickness of the casting material as a function of the depth of the final lithophane. See box 30. Again, to achieve the desired threshold levels of the grayscale image, the lithophane work can be produced within the surface of the tooling model, having the same dimensions as the final product, or on the top of the surface.

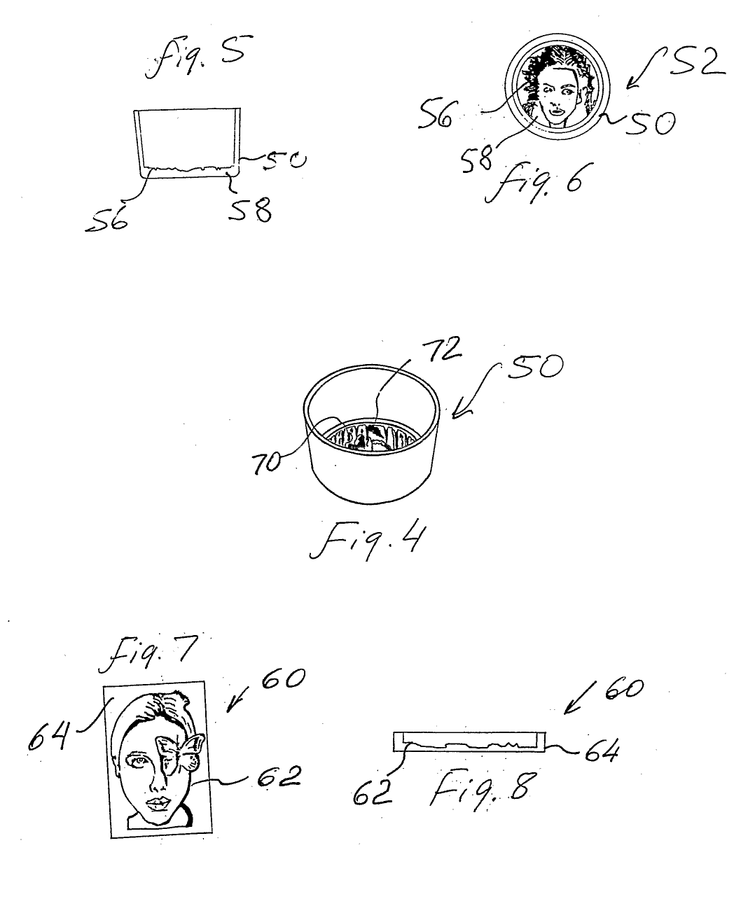

Finally, utilizing software executing on the CPU 12, the artist can create a composition by juxtaposing the created or retrieved shape of the selected final product with the 2-D image (box 32, FIG. 1). As shown in FIG. 6, as may be viewed on a screen 52 of computer, the lithophane work 56 and the actual size of the final product can be adjusted relative to one another so that the lithophane-type work 56 completely occupies the bottom 58 of the cap 50. Another embodiment illustrated in FIG. 7, features a screen-generated composition designed for a white chocolate bar 60. An image of lithophane work 62 occupies just a portion of a bottom 64. The lithophane work itself is composed of two different images: a background female image and a butterfly. FIGS. 5 and 8 represent cross-sections of the lithophane works 56, 62, respectively, both produced within the bottoms 58 and 64. As discussed above, based on the opacity of the final material and the depth of the of the lithophane works, the latter can be erected on the bottoms.

Turning back to FIG. 3, once the electronic creation of the lithophane work has been completed, it can be saved as an electronic file, as shown in box 34, to be output into the tooling model, or saved and sent to a mold maker to cut a master mold. See box 38.

FIG. 4 illustrates either the 3-D representation of the tooling model on the screen of the CPU 12. Seemingly arbitrary light 70 and dark 72 regions correspond to the desired profile of the lithophane work, as illustrated in FIGS. 5 and 6.

It will be understood that various modifications may be made to the embodiments disclosed herein. Therefore, the above description should not be construed as limiting the scope of the invention, but merely as exemplifications of the preferred embodiments. Those skilled in the art will envision other modifications within the scope and spirit of the claims appended hereto.

What is claimed is:

1. A process for creating a lithophane-type work, comprising the steps of:
selecting a 2-D image;
converting the selected 2-D image into a 3-D representation thereof; and
extrapolating a thickness and depth of the 3-D representation based on opacity and color of material into which the lithophane-type work will be produced.

2. The process of claim 1, wherein the selected 2-D image is a pictorial or photographic work, the step of selecting including reading a binary representation of the selected 2-D image.

3. The process of claim 2, wherein the binary representation of the selected 2-D image is inputted into software executing on a central processing unit (CPU) for converting the binary representation of the 2-D image into the 3-D representation.

4. The process of claim 3, wherein the inputting of the binary representation of the selected 2-D image includes scanning the 2-D image or directly loading the 2-D image into the software adapted to convert the inputted 2-D image into the 3-D representation.

5. The process of claim 2, further comprising the step of adjusting a shape and contrast of the selected 2-D to receive a desired shaped and to achieve a desired a desired level of contrast between dark and light spots on a grayscale scale of the 2-D image.

6. The process of claim 3, further comprising the step of generating a final product to be made from the material having the selected opacity and color and provided with a surface to be sculpted to carry the lithophane-type work.

7. The process of claim 6, wherein the step of generating the final product includes electronically creating an image representing the final product or retrieving the image from database of the CPU.

8. The process of claim 6, further comprising the step of adjusting a size and shape of the final product and the 3-D representation relative to one another.

9. The process of claim 8, further comprising the step of actuating a 3-D printer adapted to sculpt the lithophane-type work on the surface of a tooling model identical to the final product and made from a casting material.

10. The process of claim 9, wherein the lithophane-type work is sculpted within the surface or erected upon the surface of the tooling model dependent upon opacity of the casting material.

11. The process of claim 8, further comprising creating a transportable electronic file containing a binary representation corresponding to the adjusted shape and size of the final product and the 3-D representation of the selected 2-D image.

12. A system for creating a lithophane-type work comprising:
a central processing unit (CPU), comprising:
software executing on the CPU for selecting a 2-D image,
software executing on the CPU for converting the selected 2-D image into a 3-D representation thereof; and
software executing on the CPU for extrapolating a thickness of the 3-D representation of the selected 2-D image based on opacity and color of material of a final product to be sculpted with the lithophane-type work.

13. The system of claim 12, further comprising software executing on the CPU for adjusting the selected 2-D image to apply a desired shape to the selected image and to achieve a desired level of contrast between dark and light spots on a grayscale scale of the 2-D image.

14. The system of claim 13, further comprising software executing on the CPU for generating a final product to be made from material having opacity and color, the final product having a surface to be sculpted with the lithophane-type work.

15. The system of claim 13, further comprising software executing on the CPU for adjusting dimensions of the 3-D representation and the adjusted 2-D relative to one another.

16. The system of claim 14, further comprising a 3-D printer coupled to the CPU and operative to sculpt the lithophane-type work on the surface.

17. A article of manufacture comprising:
a surface; and
a lithophane-type work visible through the surface and having a thickness adjusted as a function of opacity of material from which the surface is made and a color of the material.

18. The article of claim 17, wherein the lithophane-type work is sculpted within the surface.

19. The article of claim 17, wherein the lithophane-type work is erected on a top of the surface.

20. The article of claim 17, wherein the article is selected from the group consisting of cans, caps, key chains, eatable items and caps each having a polygonal or annular cross-section.
